(19) United States
(12) Patent Application Publication
(10) Pub. No.: US 2005/0270821 A1
(43) Pub. Date: Dec. 8, 2005

(54) Semiconductor device and manufacturing method for same

(75) Inventor: Takashi Nakano, Fukuyama-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/145,217

(22) Filed: Jun. 6, 2005

(30) Foreign Application Priority Data
Jun. 8, 2004 (JP) 2004-169903

(51) Int. Cl. G11C 11/22

(52) U.S. Cl. 365/145

(57) ABSTRACT

The thermal processing step of thermally processing a variable resistor film in an oxidizing atmosphere is carried out after the film formation step of forming a variable resistor film (PCMO film), and ON radicals are introduced into positions of oxygen deficiency defects in the PCMO film, and thereby, the three-dimensionally coupled network structure having the PCMO perovskite structure is locally broken down so as to increase the resistivity value.

### CROSS REFERENCE TO RELATED APPLICATTION

This Nonprovisional application claims priority under 35 U.S.C. §119(a) on Patent Application No. 2004-169903 filed in Japan on Jun. 8, 2004, the entire contents of which are hereby incorporated by reference.

### BACKGROUND OF THE INVENTION

1. Field of the Invention

The present invention relates to a semiconductor device that is provided with a variable resistor film made of a PrₓCa₁₋ₓMnO₃ film of which the electrical resistance changes through the application of electrical stress, as well as to a manufacturing method for the same.

2. Description of the Related Art

Reduction in voltage and power consumption, as well as increase in speed, has been required in semiconductor devices, in particular, in CMOS devices, together with a requirement for energy conservation. The driving performance of MOS transistors that form CMOS devices have so far been secured as a result of miniaturization in the transistor structure, such as miniaturization in the gate structure and reduction in the thickness of the gate film, and thus, operation of the MOS transistors at low voltage has become possible. However, storage information is electrically stored in a memory device, and therefore, a specific information storing structure is required, making reduction in voltage and power consumption difficult. In a flash memory that is a representative non-volatile memory, for example, a tunnel oxide film having a considerable thickness (for example, approximately 10 nm) is required, in order to avoid leakage of the charge that has been stored in a floating gate. Therefore, it becomes necessary to apply a voltage of not less than 10 V to a control gate that is placed on the upper surface of this floating gate, in order to “write-in” storage information into the memory, and this becomes a factor in preventing reduction in voltage and power consumption. Furthermore, flash memories are slow in write-in speed, in comparison with FeRAMs (ferroelectric memories), and write-in properties are desired to be improved.

Meanwhile, though FeRAMs are superior to flash memories, from the point of view of write-in speed, power supply voltage and power consumption, they have the disadvantage of not being able to perform nondestructive read-out. In view of this background, research and development of non-volatile memories which are equivalent to or exceed FeRAMs in terms of low voltage, low power consumption and high speed, and which make nondestructive read-out possible, has been carried out in a variety of fields.

In recent years, it has been reported that a CMR (colossal magnetoresistive) film using Pr_{0.7}Ca_{0.3}MnO₃ exhibits a rate of change in the resistance of 1700% through the application of a pulse voltage (see S. Q. Liu, N. J. Wu, and A. Ignatiev, Appl. Phys. Lett. 76, pp. 2749 to 2751, 2000, Japanese Unexamined Patent Publication No. 2003-68983, as well as Japanese Unexamined Patent Publication No. 2003-68984). In addition, an “RRAM (resistive random access memory)” technology where this change in resistance is applied to a non-volatile memory has been published by S. T. Hsu et. al. in IEDM, 2002 (see “Novel Colossal Magneto-resistive Thin Film Nonvolatile Resistance Random Access Memory,” IEDM, pp. 193 to 196, 2002). This RRAM is superior to FeRAMs and flash memories as a non-volatile memory in the device performance, from the point of view of write-in speed, current consumption and nondestructive read-out, and has the potential to become the mainstream of the next generation of non-volatile memories. According to the above described documents, a PrₓCa₁₋ₓMnO₃ based material (hereinafter abbreviated to PCMO, where X indicates the composition ratio of 0<X<1) having a perovskite crystal structure is considered to be the most practical material for a CMR film. Thus, research on composition ratio (X) and film formation technology have been diligently carried out, in order to increase electrical properties, such as the ratio of change in resistance.

Next, a case where a change in the electrical resistance of a PCMO film is applied to write-in and erasure of a non-volatile memory is described. In the case where the film resistance is too low in the “written-in” state where the electrical resistance of a PCMO film has been converted to a low resistance state by applying a voltage pulse (electrical stress) to the PCMO film, a large current flows through the PCMO film that has been written in at the time of reading out, and therefore, measures for enforcing the peripheral circuit is required in order to lower the power consumption. In addition, the life of the PCMO film itself, which is reliable in terms of being able to withstand current, is shortened.

As a result of this, even in the case were the PCMO film is of the “low resistance state,” a certain level in the resistance value (resistivity value) becomes necessary for circuit design. It is desirable for this resistivity value to be a resistivity value in the order of 10⁴ Ωcm. This is because the difference between the high state and the low state becomes not smaller than 10 kΩcm and not greater than 500 kΩcm, even when the write-in voltage is 1 V, in the case where a PCMO film is used for a memory cell and a current at the time of write-in is not greater than 100 μA, and the difference in the current between the high state and the low state is assumed to be 2 μA, for example. According to the studies of the present inventor, a PCMO film that has been grown at a low temperature of approximately 300° C. has an amorphous crystal form exhibiting a resistivity value of approximately 10⁶ Ωcm. The PCMO film in this amorphous condition is crystallized in a thermal process during the semiconductor manufacturing process, and therefore, the crystal thereof is unstable and difficult to use as a processing material. Meanwhile, though in the case where a PCMO film in crystal form is deposited at a high temperature, a thermally stable PCMO film in crystal form is gained, the gained film has been known to exhibit a resistivity value that is lower by approximately 2 or more digits, relative to the desired resistivity in the order of 10⁴ Ωcm. Here, in the case where a PCMO film is formed at 300° C. and the quality of this PCMO film is improved by means of a thermal annealing process, the relationship of FIG. 4 has been confirmed between the annealing temperature and the resistivity.

In FIG. 4, the lateral axis indicates the annealing temperature, and the longitudinal axis indicates the resistivity value of the PCMO film. In addition, mark Δ in the figure indicates data resulting from an annealing process in an oxygen atmosphere, and mark ● indicates data resulting from an annealing process in an N₂ atmosphere, respectively.

As can be seen from FIG. 4, no change in the resistivity value of the PCMO film was confirmed up to annealing temperature T_{A}, which is a medium temperature, in O₂ annealing, while the resistivity value of the PCMO film was lowered and stabilized at annealing temperature T_{C}, which a temperature higher than temperature T_{A}. At annealing temperature T_{B}, which is halfway between temperature T_{A} and temperature T_{C}, an unstable state where low resistance value regions where the resistance is locally lowered and the high resistance state before the resistance has been lowered are mixed was gained at each point where the resistance was measured within the wafer surface. That is to say, it is suggested that the PCMO film in amorphous state that was formed at a low temperature was crystallized through the thermal process at temperature T_{C} and became of a low resistance so as to be stabilized, and that crystallization of the PCMO film occurred approximately at temperature T_{B}, which is a transfer temperature. The crystallization of the PCMO film on which annealing was carried out at temperature T_{C} was confirmed by means of TEM analysis and XRD analysis.

However, the resistivity value of the PCMO film in the “low resistance state” that was annealed at this high temperature showed up as a relativity value as low as in the order of 10² Ωcm, as confirmed in FIG. 4. As described above, a resistivity value that is higher by approximately 2 digits is required for application to an RRAM.

Meanwhile, though reduction in the resistance was slight in the case of N₂ annealing, a great number of cracks were observed on the surface of the PCMO film, as shown in FIG. 6. It is assumed that this was caused by oxygen atoms that form the PCMO film diffusing to the outside, causing oxygen deficiency defects to be contained in the PCMO film, resulting in film contraction and cracking, and thereby, that reduction in the film resistivity was restricted.

### SUMMARY OF THE INVENTION

The present invention is provided in view of these problems, and an object thereof is to provide a non-volatile memory device where nondestructive read-out and operation with low power consumption are made possible by preparing a PCMO film in a thermally stable crystal state which has no defects, such as cracking, in the PCMO film, and which has a desired resistivity in the order of 10⁴ Ωcm.

In order to achieve the above described object, a manufacturing method for a semiconductor device according to the present invention is a manufacturing method for a semiconductor device which is provided with a variable resistor film made of a PrₓCa₁₋ₓMnO₃ film of which the electrical resistance changes through the application of electrical stress, and has: the film formation step of forming the above described variable resistor film; and the thermal processing step of thermally processing the above described variable resistor film in an oxidizing atmosphere. As described above, it is the first basic feature of the process of manufacture of the semiconductor device according to the present invention.

The manufacturing method for a semiconductor device according to the present invention is also a manufacturing method for a semiconductor device which is provided with a variable resistor film made of a PrₓCa₁₋ₓMnO₃ film of which the electrical resistance changes through the application of electrical stress, and has: the film formation step of forming the above described variable resistor film; the first thermal processing step of thermally processing the above described variable resistor film in a non-oxidizing atmosphere; and the second thermal processing step of thermally processing the above described variable resistor film in an oxidizing atmosphere that contains oxygen. As described above, it is the second basic feature of the process of manufacture of the semiconductor device according to the present invention.

The manufacturing method for a semiconductor device according to the present invention is more preferably a manufacturing method for a semiconductor device which is provided with a variable resistor film made of a PrₓCa₁₋ₓMnO₃ film of which the electrical resistance changes through the application of electrical stress, and has: the film formation step of forming the above described variable resistor film; the surface processing step of carrying out plasma processing on the surface of the above described variable resistor film; and the thermal processing step of thermally processing the above described variable resistor film after the above described plasma processing in an oxidizing atmosphere. As described above, it is the third basic feature of the process of manufacture of the semiconductor device according to the present invention.

Furthermore, in the manufacturing method for a semiconductor device according to the present invention, it is preferable for the thermal processing in an oxidizing atmosphere to be carried out in the atmosphere of a gas that is selected from types of gasses that structurally include at least nitrogen atoms.

Firstly, the manufacturing method for a semiconductor device is essentially characterized in that: a variable resistor film (PCMO film) is formed in the amorphous state or in the polycrystalline state above a semiconductor substrate in the film formation step and the PCMO film is thermally processed in an oxidizing atmosphere of a gas that is selected from types of gasses that structurally include nitrogen atoms in the thermal processing step, and thereby, ON radicals can be introduced into positions of oxygen deficiency defects in this PCMO film. N of ON that has been inserted into a position of oxygen deficiency defect has three ligands, and therefore, the three-dimensionally coupled network structure of the PCMO perovskite structure is locally broken down. This breakdown in the crystal structure works so as to increase the resistivity value, and consequently, it becomes possible to form a PCMO film having a desired resistivity value. As a result of this, it becomes possible to easily implement a non-volatile memory where nondestructive read-out and operation with low power consumption are made possible by applying the manufacturing method for a semiconductor device that is firstly characterized by the present invention to a non-volatile memory device having a PCMO film.

Secondly, the manufacturing method for a semiconductor device is essentially characterized in that: a variable resistor film (PCMO film) is formed in the amorphous state or in the polycrystalline state above a semiconductor substrate in the film formation step and the first thermal processing is carried out in a non-oxidizing atmosphere, and thereby, oxygen within this PCMO film is diffused to the outside so as to introduce oxygen deficiency defects in the first thermal processing step. Subsequently, the second thermal processing is carried out in an oxidizing atmosphere of a gas selected from types of gasses that structurally include nitrogen atoms in the second thermal processing step. In this manner, the oxygen deficiency defects that have been introduced in the first thermal processing are repaired so as to be replaced with ON, and thereby, it becomes possible to form a PCMO film having a desired resistivity value. As a result of this, it becomes possible to easily implement a non-volatile memory where nondestructive read-out and operation with low power consumption are made possible by applying the manufacturing method for a semiconductor device that is secondly characterized by the present invention to a non-volatile memory device having a PCMO film.

Thirdly, the manufacturing method for a semiconductor device is essentially characterized in that: a variable resistor film (PCMO film) is formed in the amorphous state or in the polycrystalline state above a semiconductor substrate in the film formation step and the surface of the PCMO film is processed in a gas plasma atmosphere in the surface processing step after the film formation step, and thereby, the crystal structure in the surface of the PCMO film is broken down so as to be damaged. Subsequently, thermal processing is carried out in an oxidizing atmosphere of a gas selected from types of gasses that structurally include nitrogen atoms in the following thermal processing step. In this manner, the damaged layer on the surface of the PCMO film that has been introduced in plasma processing is repaired, and at the same time, ON is introduced into oxygen lattice positions, and thereby, it becomes possible to form a PCMO film having a desired resistivity value. As a result of this, it becomes possible to easily implement a non-volatile memory where nondestructive read-out and operation with low power consumption are made possible by applying the manufacturing method for a semiconductor device that is thirdly characterized by the present invention to a non-volatile memory device having a PCMO film.

### BRIEF DESCRIPTION OF THE DRAWINGS

FIGS. 1A to 1C are cross sectional diagrams for illustrating the main steps of a manufacturing process in accordance with a manufacturing method for a semiconductor device according to a first embodiment of the present invention;

FIGS. 2A to 2D are cross sectional diagrams for illustrating the main steps of a manufacturing process in accordance with a manufacturing method for a semiconductor device according to a second embodiment of the present invention;

FIGS. 3A to 3D are cross sectional diagrams for illustrating the main steps of a manufacturing process in accordance with a manufacturing method for a semiconductor device according to a third embodiment of the present invention;

FIG. 4 is a characteristic graph showing the relationship between an annealing process temperature and a resistivity value of a PCMO film;

FIG. 5 is a graph showing an improvement in the resistivity value of a PCMO film that has been prepared in accordance with the manufacturing method for semiconductor device according to the first embodiment of the present invention;

FIG. 6 is a photograph showing the film quality of a PCMO film that has been prepared in an N₂ annealing process according to the prior art; and

FIG. 7 is a circuit diagram showing an example of a memory cell and a memory cell array configuration of a semiconductor device according to the present invention.

### DETAILED DESCRIPTION OF THE INVENTION

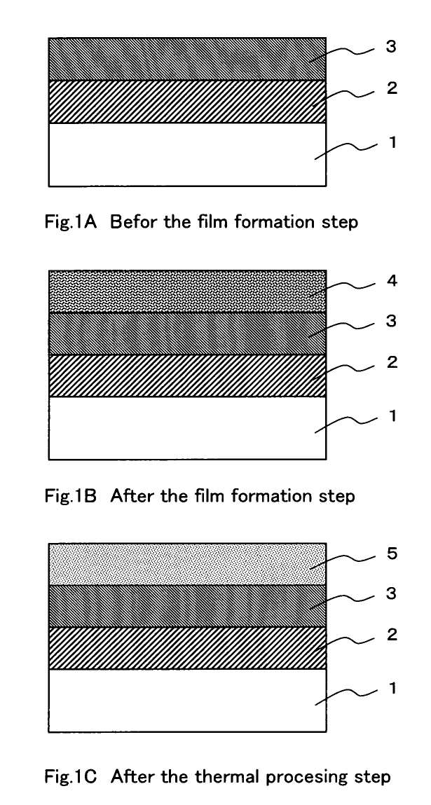

In the following, a manufacturing method for a semiconductor device according to the embodiments of the present invention (hereinafter referred to as “method of the present invention” where necessary) is described in reference to the drawings. FIGS. 1 to 3 are cross sectional diagrams for illustrating the main steps of the manufacturing process according to first to third embodiments of the method of the present invention.

### FIRST EMBODIMENT

As shown in FIG. 1, first, an insulating film 2 and a high melt point metal film 3 are formed on the surface of a semiconductor substrate 1 according to a known technology. An Si substrate 1 having a thickness of 750 μm and a diameter of approximately 200 mm (8 inches), for example, is prepared as the semiconductor substrate 1, and 1 μm of a silicon oxide film 2 (insulating film 2) and 300 nm of a Pt film 3 (high melt point metal film 3) are deposited using a commercially available CVD unit (FIG. 1A).

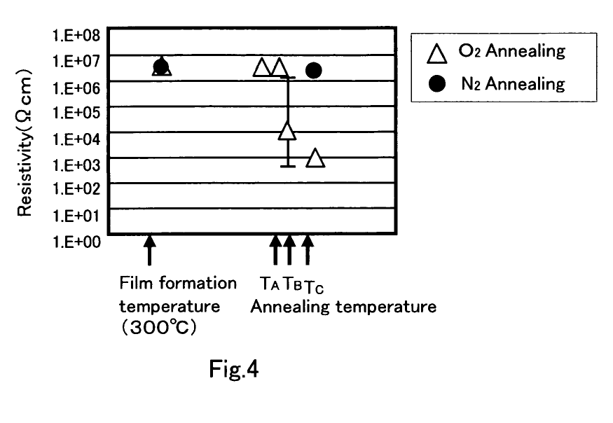

Subsequently, in the film formation step, 200 nm of a Pr_{0.7}Ca_{0.3}MnO₃ film 4 (PCMO film 4) is deposited at a film formation temperature of 300° C. according to a PVD method (FIG. 1B). Here, it is desirable for the film thickness of PCMO film 4 to be in a range from 100 nm to 600 nm. The PCMO film that has been formed at 300° C. is in crystal form in an amorphous state where coupling between the respective component atoms that form the perovskite structure is incomplete, and therefore, it exhibits a high resistivity value in the order of 10⁶ Ωcm, as shown in FIG. 4.

Next, in the thermal processing step, an annealing process is carried out on the semiconductor substrate 1 on which the PCMO film 4 in the amorphous state has been deposited in an N₂O gas atmosphere using a commercially available electrical resistance heating unit (electrical furnace) (FIG. 1C). The processing temperature needs to be a temperature where the PCMO film 4 is crystallized (temperature T_{C} shown in FIG. 4), and it is desirable for the temperature to be approximately not lower than 400° C. and not higher than 800° C. In the present embodiment, an annealing process is carried out at 600° C. for 30 minutes. The decomposing reaction shown in the following chemical reaction formulas (1) and (2) is made to occur in N₂O by means of heat. Here, “•” in (1) and (2) indicates a radical state.
N₂O→N•+NO• (1)
2N•→N₂ (2)

In this thermal processing step, crystallization of the PCMO film 4 in the amorphous state, creation of oxygen deficiency due to diffusion of oxygen to the outside in the PCMO film 4, and repairing of oxygen deficiency defects through diffusion of NO radicals that have been generated in the reaction shown in the above (1) into the PCMO film 4 sequentially occur. As a result of this annealing process, the deposited PCMO film 4 is converted to a PCMO film 5 of which the quality has been improved (oxygen deficiency defects are repaired) (FIG. 1C).

When NO is inserted into the oxygen lattice positions in the crystal structure of the PCMO film 4, nitrogen having three ligands is introduced in the position of oxygen having two ligands, causing a disturbance in the crystal structure, and consequently, the resistivity of the PCMO film 4 is increased. In the present thermal processing step, when annealing is carried out at a high temperature that exceeds 800° C., diffusion of oxygen to the outside from the PCMO film 4 accelerates, the density of oxygen deficiency defects increases, and NO radicals that have been created in the decomposing reaction of N₂O in the above (1) further dissociate and are decomposed so as to become N₂ and O₂, thus failing the introduction of desired NO radicals. In contrast, at temperature lower than 400° C., the extent of the N₂O decomposing reaction in the above (1) is low, and crystallization of the PCMO film 4 does not occur, and therefore, such a processing step cannot be adopted.

According to the method of the present invention, NO radicals that have been caused in the above (1) are used to repair oxygen deficiency defects in the PCMO film 4, and therefore, a gas that can easily generate NO radicals may be used as a material gas. NO, in addition to N₂O, in the present embodiment, can be utilized as this type of gas. A single gas atmosphere of N₂O or NO, or a mixed gas atmosphere containing these gases diluted by O₂, H₂O, N₂, Ar or He can be utilized. Gases in a peroxide state, such as O₃ and NO₂, are not desirable, because they tend to affect the NO radicals that have been generated in the above (1) in such a manner that the NO radicals are decomposed, but it is possible to utilize such gases.

In addition, though an electrical resistance heating unit (electrical furnace) is utilized for the annealing process in the thermal processing step of the present embodiment, a lamp light source heating unit, such as a flash lamp, an arc lamp and a xenon lamp, as well as a radial oxidization unit, may be utilized in order to secure the same effects.

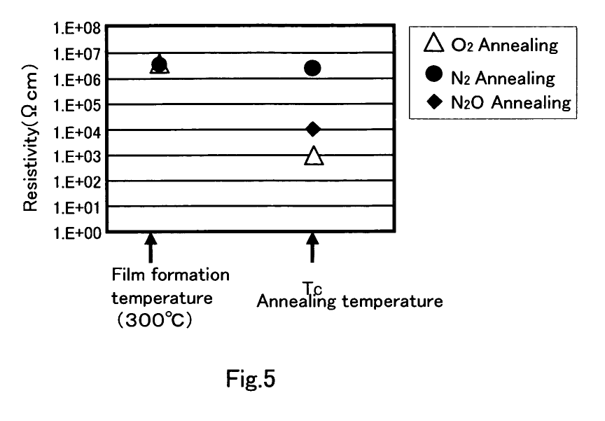

It can be confirmed from the results shown in FIG. 5 that the resistivity value (indicated by mark ♦ in FIG. 5) of the PCMO film 5 that has been fabricated by carrying out the annealing process in an N₂O gas atmosphere, as described above, is increased, and thus improved, in comparison with the resistivity value indicated by mark Δ in FIG. 5) in the case where the annealing process is carried out in a non-oxidizing atmosphere (N₂). In addition, the crystallization of the PCMO film 5 can also be confirmed, by means of an XRD analysis. It can be confirmed that cracking in the PCMO film did not occur due to N₂ annealing by means of an SEM analysis. Furthermore, the electrical properties of a memory can be confirmed in an RRAM to which a PCMO film that has bee fabricated according to the method of the present invention is applied. According to the method of the present invention, the manufacture of an RRAM device of which the power consumption has been lowered is made easier.

### SECOND EMBODIMENT

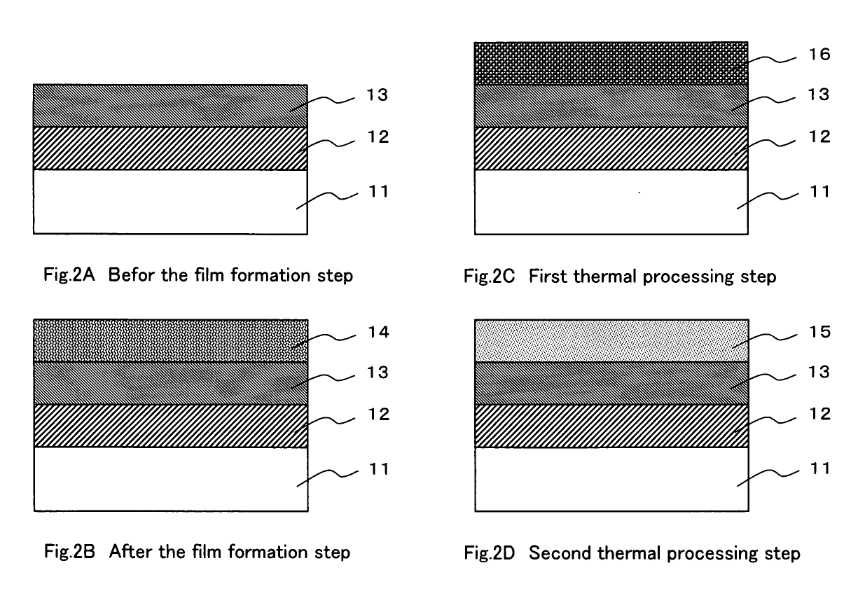

Next, a second embodiment of the method of the present invention is described in reference to FIG. 2.

First, an insulating film 12 having a film thickness of 1 μm and a high melt point metal film 13 having a film thickness of 300 nm are sequentially deposited on a semiconductor substrate 11 (FIG. 2A). For example, a CVD-Si oxide film is used as the insulating film 12, and Pt is used as the high melt point metal film 13, respectively. The above described process is carried out in the same manner as in the first embodiment.

Subsequently, in the film formation step, 200 nm of a Pr_{0.7}Ca_{0.3}MnO₃ film 14 (PCMO film 14) is deposited at a film formation temperature of 300° C. according to a PVD method (FIG. 2B). Here, it is desirable for the film thickness of the PCMO film 14 to be in a range from 100 nm to 600 nm, in the same manner as in the first embodiment.

Next, in the first thermal processing step, an annealing process is carried out on the semiconductor substrate 11 on which the PCMO film 14 has been deposited for 30 minutes in a non-oxidizing atmosphere using a commercially available electrical resistance heating unit (electrical furnace). The purpose of this first thermal processing step is to make oxygen in the PCMO film 14 diffuse to the outside and to accelerate the creation of oxygen deficiency defects in the film. Accordingly, it is desirable for the processing temperature to be a temperature that is approximately not lower than 400° C. and not higher than 800° C., so that dissociation of oxygen from the PCMO structure and diffusion of oxygen to the outside can occur. In the present embodiment, the temperature was 600° C. An arbitrary gas selected from an inert gas group, such as N₂, Ar and He, and a reducing gas group, such as H₂ and NH₃, can be utilized as the non-oxidizing atmospheric gas. In the process using a reducing gas, breakdown of the covalent bonds of oxygen in the PCMO film 14 is accelerated, and thus, the creation of oxygen deficiency defects is accelerated. As a result of the present thermal process, the PCMO film 14 is improved in quality and converted to PCMO film 16 containing oxygen deficiency defects (FIG. 2C).

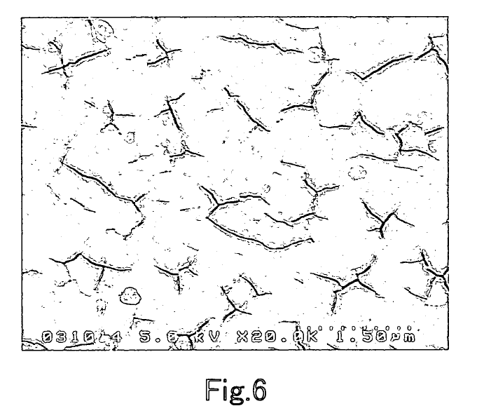

Next, in the second thermal processing step, an annealing process is carried out on the semiconductor substrate 11 above which the PCMO film 16 has been formed in an oxidizing atmosphere that includes oxygen, and the oxygen deficiency defects in the PCMO film 16 that have been created in the first thermal processing step are repaired. It is desirable for the process temperature to be a temperature that is approximately not lower than 400° C. and not higher than 800° C., in the same manner as in the first thermal processing step. An annealing process was carried out in an N₂O gas atmosphere at 600° C. for 30 minutes in the present embodiment. The purpose of using an oxidizing gas is to repair the oxygen deficiency defects that have been created in the PCMO film 16. Accordingly, a variety of gases can be utilized, as long as the type of gas that is utilized is an oxidizing gas that structurally includes oxygen atoms. A single gas, such as O₂, O₃, NO₂, H₂O, in addition to N₂O and NO that have been shown in the first embodiment, as well as a mixed gas of these, for example, can be utilized. As a result of the annealing process in the non-oxidizing atmosphere in the first thermal processing step, a considerable amount of oxygen deficiency defects have been introduced into the PCMO film 16, and therefore, an O₂, O₃, NO₂ or H₂O gas which is more strongly oxidizing can be utilized, unlike in the first embodiment, but it is desirable to utilize N₂O or NO that structurally includes nitrogen, in the same manner as in the first embodiment, from the point of view of increasing the resistivity of and improving the PCMO film. In the annealing process in the second thermal processing step, the PCMO film 16 that contains oxygen deficiency defects is again improved in quality and converted to the PCMO film 15 where the oxygen deficiency defects have been repaired (FIG. 2D). Here, the PCMO film 16 contains oxygen deficiency defects, and therefore, is in a state where stress is created in the film. In the case where the PCMO film in such a state is heated again in the second thermal processing step and an annealing process is carried out in an oxidizing atmosphere after the completion of the annealing process in the non-oxidizing atmosphere in the first thermal processing step and after the temperature within the reaction chamber has returned to room temperature, the PCMO film 16 is deformed because of its plasticity due to the above described stress in the film, and there is a risk that cracking may occur, as illustrated in FIG. 6. Accordingly, it is desirable in the first thermal processing step and in the second thermal processing step for the inside of the reaction chamber to be maintained at the same temperature, so that the respective annealing processes are carried out at the same temperature. In addition, it is desirable to switch the atmospheric gas to one of an oxidizing type gas after a process in a non-oxidizing atmosphere has been carried out in the first thermal processing step, in a manner where the annealing process in an oxidizing atmosphere is carried out as a series of sequential processes.

Though an electrical resistance heating unit (electrical furnace) is utilized for each annealing process according to the present embodiment, a lamp light source heating unit, such as a flash lamp, an arc lamp or a xenon lamp, or a radical oxidizing unit may be utilized in order to secure the same effects.

The resistivity value of the PCMO film 15 that has been fabricated according to the second embodiment of the method of the present invention, as described above, is increased and improved, in the same manner as in the first embodiment, in comparison with the resistivity value in the case where an annealing process is carried out in a non-oxidizing atmosphere (N₂).

Though an example of the PCMO film in amorphous form that has been deposited at a low temperature is described in the present second embodiment, the PCMO film in amorphous form is also converted to PCMO in crystal form having oxygen deficiency defects after the thermal processing in the first thermal processing step, and therefore, the method of the present invention can be applied to a case where a PCMO film in crystal form, in addition to a PCMO film in amorphous form, is directly formed from the beginning in the film formation step.

### THIRD EMBODIMENT

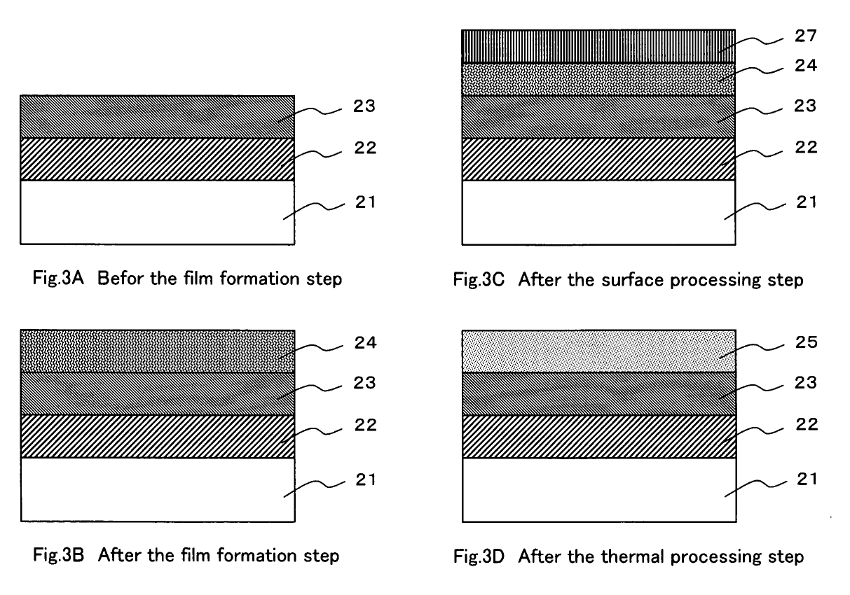

Next, the third embodiment of the method of the present invention is described in reference to FIG. 3.

First, an insulating film 22 having a film thickness of 1 μm and a high melt point metal film 23 having a film thickness of 300 nm are sequentially deposited on a semiconductor substrate 21 (FIG. 3A). For example, a CVD-Si oxide film is utilized as the insulating film 22, and Pt is utilized as the high melt point metal film 23, respectively.

Subsequently, in the film formation step, 200 nm of a Pr_{0.7}Ca_{0.3}MnO₃ film 24 (PCMO film 24) is deposited at a film formation temperature of 300° C. according to a PVD method (FIG. 3B). Here, it is desirable for the film thickness of the PCMO film 24 to be a film thickness in a range from 100 nm to 600 nm, in the same manner as in the first and second embodiments.

Next, in the surface processing step, the semiconductor substrate 21 on which the PCMO film 24 has been deposited is exposed to a plasma atmosphere using a commercially available plasma processing unit, so as to introduce a damaged layer 27 in the surface of the PCMO film 24 (FIG. 3C). The purpose of this surface processing step is to cut the covalent bonds between the component atoms of the PCMO film 24 so as to damage the surface layer of the PCMO film 24. Accordingly, it is desirable for the processing conditions to be conditions where the power is selected from values in a range from 100 W to 1000 W, and the time is selected from values in a range from approximately 10 seconds to 100 seconds. An inert gas, a reducing gas or an oxidizing gas which does not electrically affect the PCMO film 24 can be utilized as the material gas for the plasma. Appropriate gases of this type are from a group of Ar, He, N₂, H₂, NH₃, N₂O, NO, O₂, O₃, H₂O, NO₂ and the like. In the present embodiment, an N₂ gas was used as the material gas of the plasma, and 500 W was applied to the nitrogen plasma for 10 seconds.

As a result of this plasma processing, the damaged layer 27 having a thickness of approximately 100 nm is created in the surface layer of the PCMO film 24. The film thickness of the damaged layer 27 can be adjusted to an appropriate thickness by adjusting the power of the plasma processing and the time for processing.

Next, in the thermal processing step, an annealing process is carried out on the semiconductor substrate 21 where the damaged layer 27 has been created in the surface layer of the PCMO film 24 in an oxidizing atmosphere that includes oxygen, and the damaged layer 27 that has been created in the plasma processing of the surface processing step is crystallized and repaired. The processing temperature needs to be a temperature where the PCMO film 24 and the damaged layer 27 are crystallized, and a temperature of approximately not lower than 400° C. and not higher than 800° C. is desirable. In the present embodiment, the annealing process was carried out at 600° C. in an N₂O gas atmosphere for 30 minutes. As a result of this thermal processing, the covalent bonds that have been cut during the plasma processing are repaired, so that the damaged layer 27 is converted to a crystal form in a manner where an a PCMO film 25 of which the quality has been improved is formed (FIG. 3D). This thermal process also has effects of removing the plasma species that have been implanted into the damaged layer 27 of the PCMO film 24 during plasma processing from the surface of the PCMO film 24 to the outside through thermal diffusion. At the same time, however, oxygen that is a component element of the PCMO film 24 also diffuses from the inside of the film to the outside of the film. Accordingly, it is necessary for this repair to use an oxidizing gas for the adopted gas atmosphere. Here, any type of gas can be utilized, as long as it is an oxidizing gas that structurally includes oxygen atoms. A single gas, such as O₂, O₃, NO₂, H₂O, in addition to N₂O and NO which are shown in the first and second embodiments, as well as a mixed gas of these, for example, can be utilized. However, it is desirable to utilize N₂O or NO that structurally includes nitrogen, in the same manner as in the first and second embodiments, from the point of view of increasing the resistivity of and improving the PCMO film.

Though an electrical resistance heating unit (electrical furnace) is utilized for each annealing process according to the present embodiment, a lamp light source heating unit, such as a flash lamp, an arc lamp or a xenon lamp, or a radical oxidizing unit can be utilized in order to secure the same effects.

The resistivity value of the PCMO film 25 that has been fabricated according to the third embodiment of the method of the present invention, as described above, is increased, and thus, improved, in approximately the same manner as in the first embodiment, in comparison with the resistivity value in the case where the annealing process is carried out in a non-oxidizing atmosphere (N₂).

Though a PCMO film in amorphous form that has been deposited at a low temperature is utilized in the present third embodiment, the PCMO film in amorphous form is converted to a crystal form in the thermal process under an oxidizing atmosphere in the thermal processing step, and therefore, the method of the present invention can be applied to a case where a PCMO film in crystal form, in addition to a PCMO film in amorphous form, is directly formed from the beginning in the film formation step.

### FOURTH EMBODIMENT

Next, a semiconductor device provided with a PCMO film that has been prepared in accordance with the method of the present invention described above in the first to third embodiments is simply described.

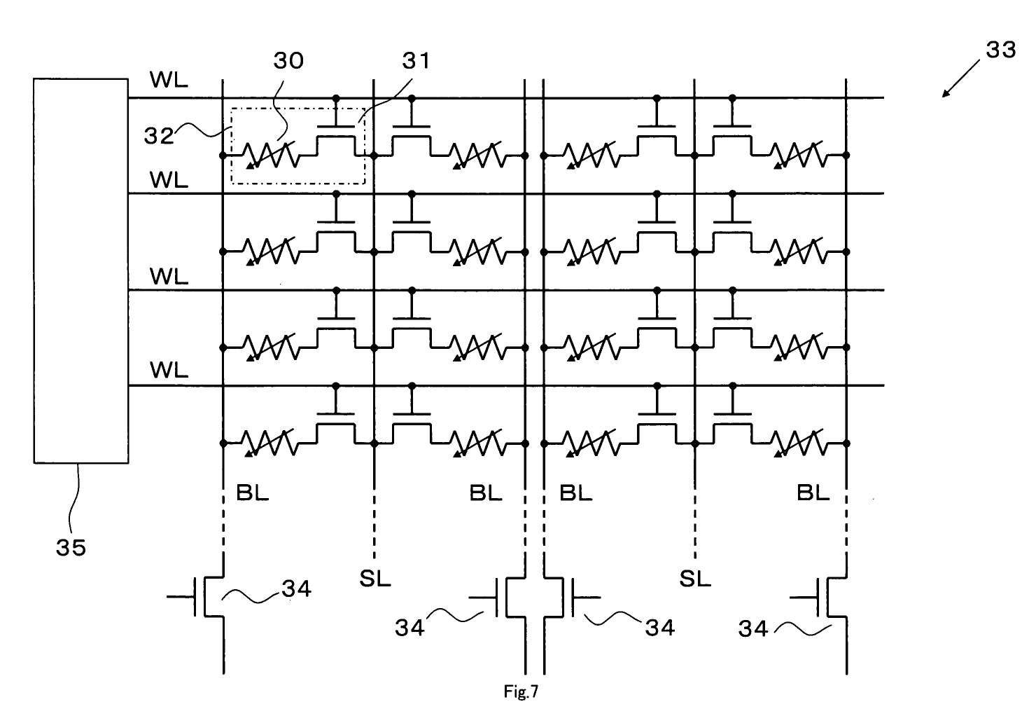

An RRAM (resistive random access memory) where the properties of a PCMO film of which the electrical resistance changes through the application of electrical stress are used can be cited as a semiconductor device provided with a PCMO film. An RRAM is a type of non-volatile memory device where a number of memory cells, each of which stores data of 1 bit (2 values) or three or more values are arranged in matrix form on a semiconductor substrate so as to form a memory cell array which is formed so that data of a number of bits can be stored and read out in the same manner as conventional non-volatile memory devices that use other types of memory elements. A variety of forms exist for the configuration of a memory cell and a memory cell array, and a memory cell and a memory cell array configuration which are utilized in other non-volatile memory devices can be generally used. As shown in FIG. 7, for example, a memory cell 32 is formed by connecting one end of a memory element 30 (hereinafter referred to as “RRAM element”) made of a PCMO film to the drain electrode of a selecting transistor 31, and a number of memory cells 32 are arranged in the row direction and in the column direction so as to form a matrix, providing a memory cell array 33. Furthermore, the gate electrodes of the selecting transistors 31 of respective memory cells 32 in the same row are connected to a common word line WL, the other ends of the RRAM elements 30 of respective memory cells 32 in the same column are connected to a common bit lines BL, and the source electrodes of the selecting transistors 31 of respective memory cells 32 in the same column are connected to a common source line SL, and thereby, an arbitrary memory cell 32 can be selected from the memory cell array 33 for the purpose of a memory operation, such as data readout or write-in, in the configuration.

Next, a variety of memory operations of an arbitrary memory cell 32 within the memory cell array 33 are briefly described. First, the readout operation is described. A bit line selecting transistor 34 is operated so that a bias voltage can be applied to a bit line BL that is connected to the RRAM element 30 of a selected memory cell 32, and thus, 1.5 V, for example, is applied to the selected bit line BL. At the same time, the word line WL that is connected to the gate electrode of the selecting transistor 31 of the memory cell 32 which is the object of readout is set at a high level (for example, 7 V) by means of a word line driver 35, and thus, this selecting transistor 31 is turned on. In addition, the source electrode of the selecting transistor 31 (which is connected to the common source line SL) is set at a reference voltage, for example, the ground potential of 0 V, and thereby, a current path to the ground potential from the bias voltage of the selected bit line BL through the RRAM element 30 and the selecting transistor 31 is created. Meanwhile, unselected word lines WL of the unselected memory cells are set at a low level (for example, the ground potential of 0 V) by means of the word line driver 35, and the unselected bit lines BL are set at a low level or to a high impedance (open state), and thereby, no current path that passes through an RRAM element 30 other than the RRAM element 30 of the memory cell 32 that has been selected by the readout bit line is created. In such a situation, only a change in the resistance of the selected RRAM element 30 is exhibited as a change in the current that flows through the bit line BL, and this change in the current is determined by a readout circuit (not shown), and thereby, the data that is stored in the selected memory cell can be read out with precision. As a result of this, the RRAM element can be practically utilized as a memory element.

Here, the PCMO film that forms an RRAM element 30 has been fabricated in accordance with the method of the present invention, and therefore, the quality of the film in the state where microscopic crystals and crystals are mixed, of which the resistivity is higher than the resistivity of a film in the case where a thermal process is carried out in a non-oxidizing gas atmosphere by approximately one to two digits, has been improved. As a result of this, a memory cell current in the stored state where the RRAM element 30 becomes the state of low resistance is suppressed, and thus, reduction in the power consumption at the time of the readout operation is made possible.

Next, the write-in operation is described. Here, the state where the resistivity value of an RRAM element 30 is greater than the resistance value that becomes a reference is assumed to be a written in state, and the state where the resistivity value of an RRAM element 30 is smaller than the reference is assumed to be an erased state. A bit line selecting transistor 34 is operated so that a bias voltage can be applied to the bit line BL which is connected to the selected RRAM element 30, and 3 V, for example, is applied to the selected bit line BL. At the same time, the word line WL that is connected to the gate electrode of the selecting transistor 31 which is connected to the RRAM element 30 to be written in is set at a high level (for example, 7 V), by means of a word line driver 35, and the selecting transistor 31 is turned on. In addition, the source electrode of the selecting transistor 31 (which is connected to the common source line SL) is set at a predetermined value (for example, the ground potential of 0 V), and thereby, a current path to the ground potential from the bias voltage of the selected bit line BL through the RRAM element 30 and the selecting transistor 31 is created, and thus, write-in into the selected memory cell 30 is carried out. Meanwhile, the unselected word lines WL of the unselected memory cells are set at a low level (for example, the ground potential of 0 V), and thereby, no current path to the ground potential from an RRAM element 30 of an unselected memory cell through a selecting bit line BL is created, and thus, no write-in is provided.

Here, the PCMO film that forms each RRAM element 30 is fabricated in accordance with the method of the present invention, and therefore, the quality of the film in the state where microscopic crystals and crystals are mixed, of which the resistivity is higher than the resistivity of a film in the case where a thermal process is carried out in a non-oxidizing gas atmosphere by approximately one to two digits, has been improved. As a result of this, the memory cell current (write-in current) in the state of low resistance before the RRAM element 30 has been written into is suppressed, and thus, reduction in the power consumption at the time of the write-in operation is made possible.

Next, a block erasure for collectively erasing a block unit is described. Bit line selecting transistors 34 are operated so that a bias voltage can be applied to all of the bit lines BL which are connected to the RRAM elements 30 of the memory cells 32 within a block, and a ground potential of 0 V, for example, is applied to all of the bit lines BL. At the same time, the word lines WL which are connected to the gate electrodes of the selecting transistors 31 of all of the memory cells 32 are set at a high level (for example, 7 V), and thus, the selecting transistors 31 are turned on. In addition, the source electrodes of the selecting transistors 31 (which are connected to the common source line SL) are set at a reference voltage, for example, 3 V, and thereby, a current path to the bit lines BL at the ground potential of 0 V from the bias voltage of the common source line SL through all of the selecting transistors 31 and the RRAM elements 30 within the block is created in the direction opposite to that at the time of the write-in operation. As a result of the above described operation, it becomes possible to carry out an erasure operation on all of the memory cells 32 within the block.

Here, the PCMO film that forms each RRAM element 30 is fabricated in accordance with the method of the present invention, and therefore, the quality of the film in the state where microscopic crystals and crystals are mixed, of which the resistivity is higher than the resistivity of a film in the case where a thermal process is carried out in a non-oxidizing gas atmosphere by approximately one to two digits, has been improved. As a result of this, the memory cell current (erasure current) is suppressed, even when the RRAM elements 30 are transferred to the state of low resistance together with the progress of erasure, and thus, reduction in the power consumption at the time of the erasure operation is made possible.

A variety of configurations of the memory cell of the RRAM may be considered, such as a configuration where a memory cell 32 is made only of an RRAM element 30 without the selecting transistor 31, a configuration where a selecting transistor 31 is made of a bipolar transistor instead of a MOSFET, and a configuration where a diode is used instead of the selecting transistor 31, in addition to the configuration shown in FIG. 7. In addition, a variety of memory cell arrays which are formed of such memory cells may be considered, without being limited to the configuration shown in FIG. 7.

In addition, a non-volatile memory semiconductor device where nondestructive readout is possible and which is superior to conventional non-volatile memory devices in terms of reduction in the voltage, reduction in power consumption and an increase in the speed can be easily implemented by using an RRAM having a PCMO film that is fabricated in accordance with the method of the present invention.

Although the present invention has been described in terms of a preferred embodiment, it will be appreciated that various modifications and alterations might be made by those skilled in the art without departing from the spirit and scope of the invention. The invention should therefore be measured in terms of the claims which follow.

1. A manufacturing method for a semiconductor device, wherein
said semiconductor device comprises:
a variable resistor film made of a PrₓCa₁₋ₓMnO₃ film of which the electrical resistance changes through the application of electrical stress, and
said manufacturing method has:
the film formation step of forming said variable resistor film; and the thermal processing step of thermally processing said variable resistor film in an oxidizing atmosphere.

2. The manufacturing method for a semiconductor device according to claim 1, wherein
said oxidizing atmosphere in said thermal processing step is gained by using a type of gas that contains at least nitrogen.

3. The manufacturing method for a semiconductor device according to claim 2, wherein
said type of gas that contains at least nitrogen is a single gas of N₂O or NO or a mixed gas where either of said single gasses is diluted with a dilution gas, such as O₂, H₂O, N₂, Ar or He.

4. The manufacturing method for a semiconductor device according to claim 1, wherein
the processing temperature in said thermal processing step is in a temperature range of not lower than 400° C. and not higher than 800° C.

5. The manufacturing method for a semiconductor device according to claim 1, wherein
in said thermal processing step, the thermal processing is carried out using at least any one of processing systems from among an electrical resistor heating furnace, a lamp light source heating unit and a radical oxidizing unit.

6. The manufacturing method for a semiconductor device according to claim 1, wherein
in said film formation step, said variable resistor film is formed as a film in the amorphous state or in the microscopic crystalline state by using any one of a CVD method, a PVD method and a spin coating method.

7. A semiconductor device, comprising:
a variable resistor film made of a PrₓCa₁₋ₓMnO₃ film of which the electrical resistance changes through the application of electrical stress, which is prepared in accordance with a manufacturing method for a semiconductor device according to claim 1, wherein
said variable resistance film is in a state where microscopic crystals and crystals are mixed.

8. A manufacturing method for a semiconductor device, wherein
said semiconductor device comprises:
a variable resistor film made of a PrₓCa₁₋ₓMnO₃ film of which the electrical resistance changes through the application of electrical stress, and
said manufacturing method has:
the film formation step of forming said variable resistor film; the first thermal processing step of thermally processing said variable resistor film in a non-oxidizing atmosphere; and the second thermal processing step of thermally processing said variable resistor film in an oxidizing atmosphere that contains oxygen.

9. The manufacturing method for a semiconductor device according to claim 8, wherein
said non-oxidizing atmosphere in said first thermal processing step is gained by using at least one type of gasses from among N₂, Ar, He, H₂ and NH₃.

10. The manufacturing method for a semiconductor device according to claim 8, wherein
said oxidizing atmosphere in said second thermal processing step is gained by using at least one type of gasses from among N₂O, NO, O₂, O₃, H₂O and NO₂.

11. The manufacturing method for a semiconductor device according to claim 8, wherein
each of the processing temperatures in said first thermal processing step and said second thermal processing step is in a temperature range of not lower than 400° C. and not higher than 800° C.

12. The manufacturing method for a semiconductor device according to claim 8, wherein
said first thermal processing step and said second thermal processing step are sequentially carried out.

13. A semiconductor device, comprising:
a variable resistor film made of a PrₓCa₁₋ₓMnO₃ film of which the electrical resistance changes through the application of electrical stress, which is prepared in accordance with a manufacturing method for a semiconductor device according to claim 8, wherein
said variable resistance film is in a state where microscopic crystals and crystals are mixed.

14. A manufacturing method for a semiconductor device, wherein
said semiconductor device comprises:
a variable resistor film made of a PrₓCa₁₋ₓMnO₃ film of which the electrical resistance changes through the application of electrical stress, and
said manufacturing method has:
the film formation step of forming said variable resistor film; the surface processing step of carrying out plasma processing on the surface of said variable resistor film; and the thermal processing step of thermally processing said variable resistor film after said plasma processing in an oxidizing atmosphere.

15. The manufacturing method for a semiconductor device according to claim 14, wherein
in said surface processing step, a plasma made of ions or radicals which have been derived from at least one type of gas from among H₂, He, N₂, O₂, Ar, NH₃, N₂O, NO, O₂, O₃, H₂O and NO₂ is used.

16. The manufacturing method for a semiconductor device according to claim 14, wherein
said oxidizing atmosphere in said thermal processing step is gained including at least an N₂O or NO gas.

17. The manufacturing method for a semiconductor device according to claim 14, wherein
the processing temperature in said thermal processing step is in a temperature range of not lower than 400° C. and not higher than 800° C.

18. A semiconductor device, comprising:
a variable resistor film made of a PrₓCa₁₋ₓMnO₃ film of which the electrical resistance changes through the application of electrical stress, which is prepared in accordance with a manufacturing method for a semiconductor device according to claim 14, wherein
said variable resistance film is in a state where microscopic crystals and crystals are mixed.
